(19) United States
(12) Patent Application Publication
(10) Pub. No.: US 2018/0095936 A1
(43) Pub. Date: Apr. 5, 2018

(54) OPTIMIZING A MANUFACTURING OR FABRICATION PROCESS USING AN INTEGRATED BAYESIAN STATISTICS AND CONTINUUM MODEL APPROACH

(71) Applicant: Board of Regents, The University of Texas System, Austin, TX (US)

(72) Inventors: Roger T. Bonnecaze, Austin, TX (US); Meghali Chopra, Austin, TX (US)

(21) Appl. No.: 15/286,380

(22) Filed: Oct. 5, 2016

(51) Int. Cl. G06F 17/18; H01J 37/32

(52) U.S. Cl. CPC G06F 17/18; H01J 2237/334; G06F 2217/10; H01J 37/32009

(57) ABSTRACT

A method, system and computer program product for optimizing a manufacturing or fabrication process. A set of parameters for a selected model is received. A prior distribution of values for the model parameters is adopted which summarizes any known information for the model parameters. A utility function which reflects a purpose of an experiment is specified. After selecting an experimental design from a set of experimental designs and selecting experimental data from a sample space of data based on the selected experimental data, a Bayesian technique is used to calculate a posterior distribution of values for the model parameters based on the selected experimental data and the prior distribution of values for the model parameters. In response to the model uncertainty reaching a desired threshold, the posterior distribution of values for the model parameters is selected to be used to adjust the manufacturing/fabrication process to manufacture/fabricate a device.

### GOVERNMENT INTERESTS

This invention was made with government support under Grant No. EEC1160494 awarded by the National Science Foundation. The U.S. government has certain rights in the invention.

### TECHNICAL FIELD

The present invention relates generally to fabrication and manufacturing processes, and more particularly to optimizing the manufacturing or fabrication process using an integrated Bayesian statistics and continuum model approach.

### BACKGROUND

Currently, manufacturing and fabrication processes (e.g., processes for manufacturing magnetic memory, nanophotonic devices, metamaterial structures, biomedical applications, etc.) are optimized using the time consuming and expensive approach of trial and error. Some processes may take up to a year to be fully optimized. Shortening this development time offers a clear opportunity to save time and money. Importantly, for semiconductor tool manufacturers, a shorter time to development can mean millions in tool sales.

Currently, there are techniques that attempt to shorten the development time, such as the Design of Experiment (DOE). DOE is the design of any task that aims to describe or explain the variation of information under conditions that are hypothesized to reflect the variation. In particular, the design may introduce conditions that directly affect the variation. Also, natural conditions that influence the variation may be selected for observation.

However, such a technique still often requires a large number of experiments and neglects information that might be gained from an understanding of process physics.

As a result, there is not currently a technique for optimizing processes, such as manufacturing and fabrication processes, that utilizes a limited number of experiments to identify the optimal process conditions in a short time frame.

### SUMMARY

In one embodiment of the present invention, a method for optimizing a manufacturing or fabrication process comprises receiving a selection of a model. The method further comprises receiving a set of parameters for the selected model. The method additionally comprises adopting a prior distribution of values for the set of model parameters which summarizes any known information for the set of model parameters. Furthermore, the method comprises specifying a utility function which reflects a purpose of an experiment. Additionally, the method comprises selecting an experimental design from a set of experimental designs which maximizes the utility function. In addition, the method comprises selecting experimental data from a sample space of data based on the selected experimental design. The method further comprises using a Bayesian technique to calculate a posterior distribution of values for the set of model parameters based on the selected experimental data and the prior distribution of values for the set of model parameters. The method additionally comprises selecting the posterior distribution of values for the set of model parameters in response to a model uncertainty reaching a threshold. Furthermore, the method comprises adjusting, by a processor, the manufacturing or fabrication process to manufacture or fabricate a device using the selected posterior distribution of values for the set of model parameters.

Other forms of the embodiment of the method described above are in a system and in a computer program product.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates an embodiment of the present invention of the hardware configuration of a computing device which is representative of a hardware environment for practicing the present invention;

FIG. 2 is a flowchart of a method for optimizing a manufacturing or fabrication process in accordance with an embodiment of the present invention;

FIGS. 3A-3B are graphs illustrating a distribution of parameter estimates for posterior density for parameters A and B, respectively, using Gibbs sampling and Markov chain Monte Carlo (MCMC) methods in Bayesian inference in accordance with an embodiment of the present invention;

FIG. 4 illustrates a region that is randomly placed in a dart board comprising a 20 by 20 grid of x-y values in accordance with an embodiment of the present invention;

FIG. 5 illustrates the “brute force” method used by the blindfolded player to precisely and accurately identify the process window of the target in accordance with an embodiment of the present invention;

FIGS. 6A-6F illustrate the predicted target area using Bayesian inference in accordance with an embodiment of the present invention;

FIG. 7 is a coarse grid for the target space in accordance with an embodiment of the present invention;

FIGS. 8A-8C illustrate the target predictions based off of 25 sequential experiments using μ−σ, μ, and μ+σ, respectively, in accordance with an embodiment of the present invention;

FIG. 9 shows a comparison between the traditional full factorial design method and the integrated approach over a series of synthetic experiments in accordance with another embodiment of the present invention; and

FIG. 10 illustrates the experimental and predicted etch rates for different processing conditions in accordance with an embodiment of the present invention.

### DETAILED DESCRIPTION

Nanosculpting, the fabrication of two- and three-dimensional shapes at the nanoscale, will enable applications in photonics, metamaterials, multi-bit magnetic memory, and bio-nanoparticles. A key requirement to achieving nanomanufacturing viability of nanosculptures is maintaining image fidelity through each step of the imprinting and etching processes. In particular, polymer densification during UV curing, plastic deformation during template removal, and local variations in etch rates can distort the imprinted image. Currently, the standard process optimization approach for error reduction is based on trial and error. This approach is extremely costly and time-consuming, with some processes taking up to a year to fully optimize.

As discussed herein, the present invention provides a process optimization technique that uses an integrated continuum model and a Bayesian experimental design and inference approach. The process optimization technique of the present invention allows for faster experimental calibration of models with large numbers of unknown parameters and enhanced process prediction capabilities. While the following discusses the present invention in connection with optimizing the dry etch rate predictions of magnesium oxide, the principles of the present invention may be applied to any manufacturing or fabrication process. A person of ordinary skill in the art would be capable of applying the principles of the present invention to such implementations. Further, embodiments applying the principles of the present invention to such implementations would fall within the scope of the present invention.

When calibrating models with experimental data, the accepted convention is to fit unknown parameters using design of experiment (DOE) methods including screening, experiments, mixture experiments, response surface analysis, evolutionary operations, and full or fractional factorial design. These design approaches do not take into account prior knowledge about the unknown parameters, and often require large numbers of experiments for precise fits. This approach is especially cumbersome for etch models where there are a number of unknown or difficult to measure parameters.

In nanomanufacturing, the effects of design parameters on process output are challenging to describe with purely phenomenological models. This mandates large data collection efforts which can be expensive and time consuming. The present invention introduces a novel methodology for reducing the time and cost associated with data collection and stochastic modeling by using simplified continuum models and sequential Bayesian experimental design and inference. While the following discusses the present invention in connection with applying this technique to dry etching, the principles of the present invention can be applied to all nanomanufacturing processes where continuum modeling can provide some prior knowledge about the physics of the system.

Dry etching is one of the most challenging fabrication steps to optimize due to its large number of process variables and the complexity of the gas chemistry and surface kinetics taking place in the reactor where hundreds of physical and chemical reactions occur in parallel. Current optimization schemes for etching rely primarily on a trial and error approach. Qualitative relationships based on experience are used to “tune” etch parameters, however, this approach does not provide for extrapolation to new devices. Many feature and reactor scale dry etch models and software exist today for dry etching. Nevertheless, these models are rarely used in practice due to their inability to adapt to new materials and gas chemistries, to capture local variations in etch rate due to complex pattern densities, their significant parameter input requirements, and their lengthy simulation times. These obstacles can be overcome with the present invention which allows prior information about the system physics to be incorporated into the experimental design decisions.

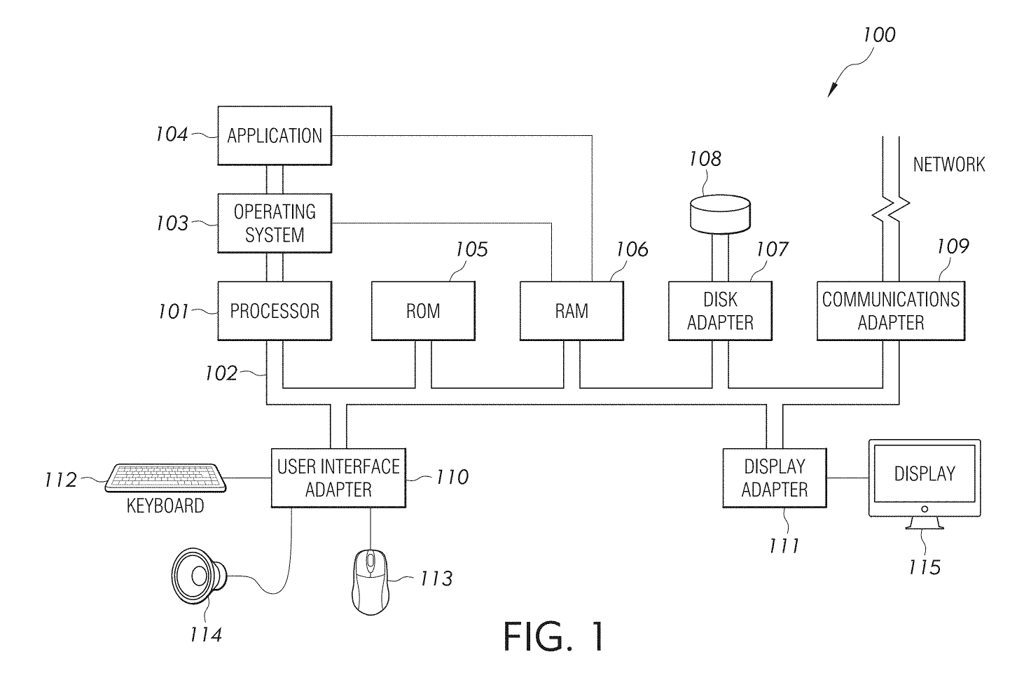

Referring now to the Figures in detail, FIG. 1 illustrates an embodiment of the present invention of the hardware configuration of a computing device 100 which is representative of a hardware environment for practicing the present invention. Computing device 100 may be any type of computing device (e.g., portable computing unit, Personal Digital Assistant (PDA), smartphone, laptop computer, mobile phone, navigation device, game console, desktop computer system, workstation, Internet appliance and the like) configured with the capability of optimizing the nanomanufacturing process using an integrated Bayesian statistics and continuum model approach. Referring to FIG. 1, computing device 100 may have a processor 101 coupled to various other components by system bus 102. An operating system 103 may run on processor 101 and provide control and coordinate the functions of the various components of FIG. 1. An application 104 in accordance with the principles of the present invention may run in conjunction with operating system 103 and provide calls to operating system 103 where the calls implement the various functions or services to be performed by application 104. Application 104 may include, for example, an application for optimizing the nanomanufacturing process using an integrated Bayesian statistics and continuum model approach as discussed further below.

Referring again to FIG. 1, read-only memory (“ROM”) 105 may be coupled to system bus 102 and include a basic input/output system (“BIOS”) that controls certain basic functions of computing device 100. Random access memory (“RAM”) 106 and disk adapter 107 may also be coupled to system bus 102. It should be noted that software components including operating system 103 and application 104 may be loaded into RAM 106, which may be computing device's 100 main memory for execution. Disk adapter 107 may be an integrated drive electronics (“IDE”) adapter that communicates with a disk unit 108, e.g., disk drive. It is noted that the program for optimizing the nanomanufacturing process using an integrated Bayesian statistics and continuum model approach may reside in disk unit 108 or in application 104.

Computing device 100 may further include a communications adapter 109 coupled to bus 102. Communications adapter 109 may interconnect bus 102 with an outside network thereby allowing computing device 100 to communicate with other devices.

I/O devices may also be connected to computing device 100 via a user interface adapter 110 and a display adapter 111. Keyboard 112, mouse 113 and speaker 114 may all be interconnected to bus 102 through user interface adapter 110. A display monitor 115 may be connected to system bus 102 by display adapter 111. In this manner, a user is capable of inputting to computing device 100 through keyboard 112 or mouse 113 and receiving output from computing device 100 via display 115 or speaker 114. Other input mechanisms may be used to input data to computing device 100 that are not shown in FIG. 1, such as display 115 having touch-screen capability and keyboard 112 being a virtual keyboard. Computing device 100 of FIG. 1 is not to be limited in scope to the elements depicted in FIG. 1 and may include fewer or additional elements than depicted in FIG. 1.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

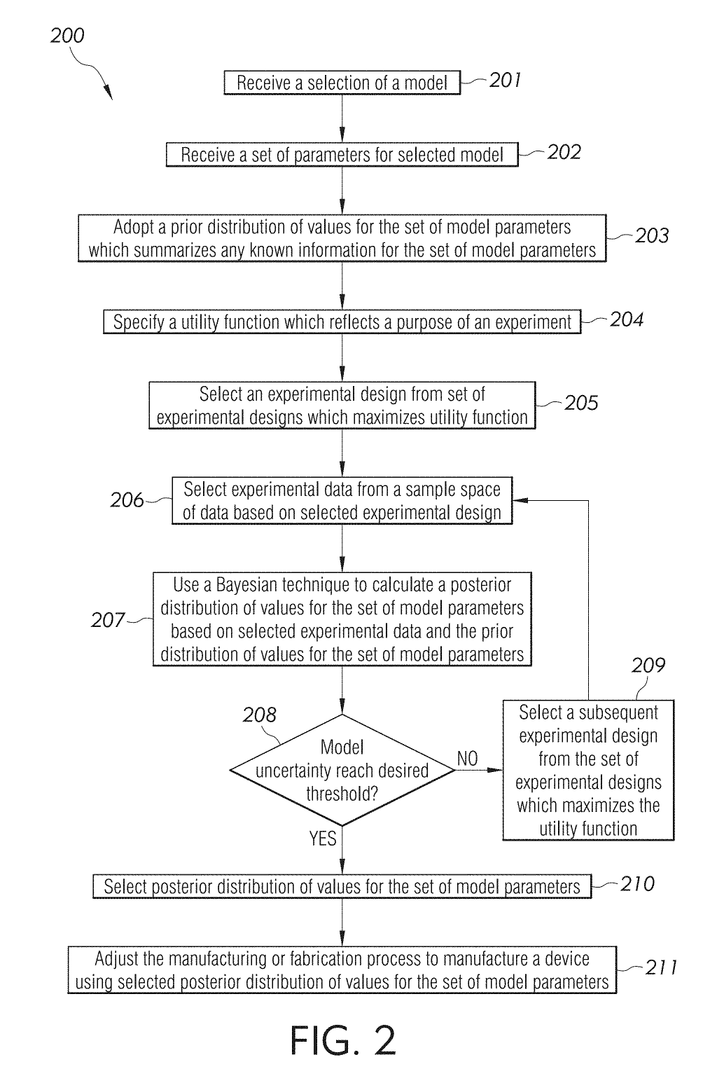

As discussed above, the current approach for optimizing nanomanufacturing processes is based on trial and error. This approach is extremely costly and time-consuming, with some processes taking up to a year to fully optimize. The present invention optimizes nanomanufacturing processes in a quicker manner using a fewer number of experiments by using continuum models in combination with Bayesian experimental design and Bayesian inference as discussed below in connection with FIG. 2.

FIG. 2 is a flowchart of a method 200 for optimizing a manufacturing or fabrication process in accordance with an embodiment of the present invention.

Referring to FIG. 2, in conjunction with FIG. 1, in step 201, computing device 100 receives a selection of a model (e.g., plasma etch or deposition model).

In step 202, computing device 100 receives a set of parameters (unknown parameters) for the selected model.

In step 203, computing device 100 adopts a probability distribution (referred to herein as the “prior distribution”) of values for the set of model parameters (parameters received in step 202) which summarizes any known information for the set of model parameters.

In step 204, computing device 100 specifies a utility function which reflects a purpose of an experiment.

In step 205, computing device 100 selects an experimental design from a set of experimental designs which maximizes the utility function.

In step 206, computing device 100 selects experimental data from a sample space of data based on the selected experimental design.

In step 207, computing device 100 uses a Bayesian technique to calculate a “posterior distribution” of values for the set of model parameters based on the selected experimental data and the prior distribution of values for the set of model parameters.

In step 208, a determination is made by computing device 100 as to whether the model uncertainty (model uncertainty prediction capability) reaches a desired threshold. For example, a determination is made by computing device 100 as to whether the model uncertainty is below 2% (meaning that the model is inaccurately predicting less than 2% of the time). In another example, a determination is made by computing device 100 as to whether the model certainty (model prediction capability) is above 96% (meaning that the model is accurately predicting greater than 96% of the time). In one embodiment, the threshold is user-selected.

If the model uncertainty does not reach the desired threshold, then, in step 209, computing device 100 selects a subsequent experimental design from the set of experimental designs which maximizes the utility function.

Computing device 100 then selects experimental data from a sample space of data based on the selected experimental design in step 206.

If, however, the model uncertainty reaches the desired threshold, then, in step 210, computing device 100 selects the posterior distribution of values for the set of model parameters.

In step 211, computing device 100 adjusts the nanomanufacturing process to manufacture a device (e.g., memory devices, nanophotonic devices, metamaterial structures, biomedical devices) using the selected posterior distribution of values for the set of model parameters. In one embodiment, such an adjustment involves calibrating the model in a technical field (e.g., subsurface m modeling, biochemical pathways, chemical kinetic and material properties) by fitting the distribution of values for the model parameters. In one embodiment, the model is a continuum model. In one embodiment, the model is a plasma etch or deposition model.

A more detailed discussion regarding method 200 is provided below.

In one embodiment, unknown and difficult to measure model parameters are determined using a targeted Bayesian experimental design. In Bayesian design, an unknown parameter θ is assumed to be random. A probability distribution called the “prior distribution” is adopted for 8 which summarizes any known information. This distribution is independent of the information provided by the data (selected from sample space). The posterior distribution given by Bayes rule allows inference of θ based on the data and prior distribution.

p(θ|y)=p(y|θ)p(θ)/p(y) (1)

where p(θ) is the prior density, p(y|θ) is the likelihood function of θ, p(θ|y) is the posterior density of θ given y, and p(y) is the evidence.

In optimizing the experimental design, a design η is chosen from some set H, and data y from a sample space Y is observed. Applying Bayesian analysis, a utility function is specified which reflects the purpose of the experiment, treating the design choice as a decision problem, and then maximizing the expected utility. In one embodiment, the expected utility of the best decision may be given by

$$I ( η ) = {\int }_{y}^{ } {\int }_{Θ}^{ } i ( η , θ , y ) p ( θ \vert y , η ) p ( y \vert η ) d θ dy \qquad ( 2 )$$

where i(η,θ,y) is a utility function, I(η) is the expected utility, ⊖ is the support of p(θ), and y is the support of p(y). In one embodiment, a utility function is used based on the relative entropy, or Kullback-Leibler (KL) divergence, from posterior to the prior so that

i(η,θ,y)=∫p(θ*|y,η)ln(p(θ*|y,η)/p(θ*))dθ* (3)

where θ* is a dummy variable representing the parameters. Using Monte Carlo sampling, the resulting utility function expression can be simplified to:

$$I ( η ) = \frac{1}{{N}_{1}} {\sum }_{i = 1}^{{N}_{1}} [ ln ( p ( {y}^{( i )} \vert {θ}^{( i )} , η ) - ln ( \frac{1}{{N}_{2}} {\sum }_{j = {N}_{1} + 1}^{{N}_{1} + {N}_{2}} ( p ( {y}^{( i )} \vert {θ}^{( i , j )} , η ) ) ] \qquad ( 4 )$$

A large KL divergence implies that the data y decreases entropy in θ so that the data is more informative for parameter reference.

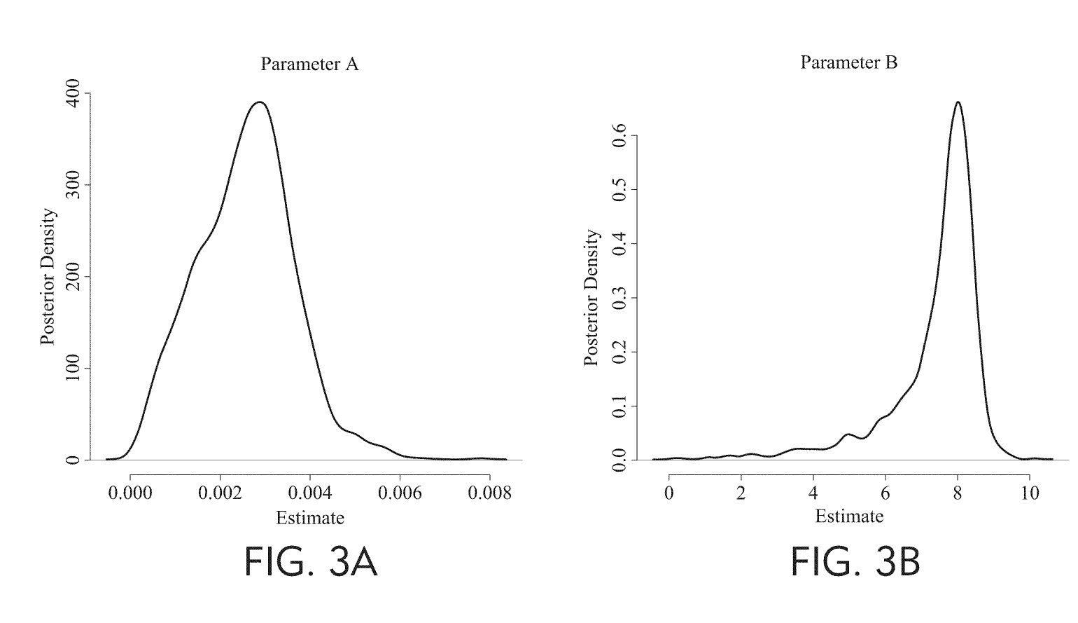

Once the optimal experimental set has been determined and the experiments have been executed, Bayesian techniques, such as Gibbs sampling, are used to infer the unknown parameters. In Gibbs sampling, the observed data is incorporated into the sampling process by creating separate variables for each piece of observed data. These variables are fixed in relation to the observed value so that the distribution of the remaining variables is then a posterior distribution conditioned on the data as shown in FIGS. 3A-3B.

FIGS. 3A-3B are graphs illustrating a distribution of parameter estimates for posterior density for parameters A and B, respectively, using Gibbs sampling and Markov chain Monte Carlo (MCMC) methods in Bayesian inference in accordance with an embodiment of the present invention.

The distribution of parameter estimates is then fed back into the continuum model and the next experiment to perform based on the specified optimality criterion is determined.

The following discusses applying method 200 to a target.

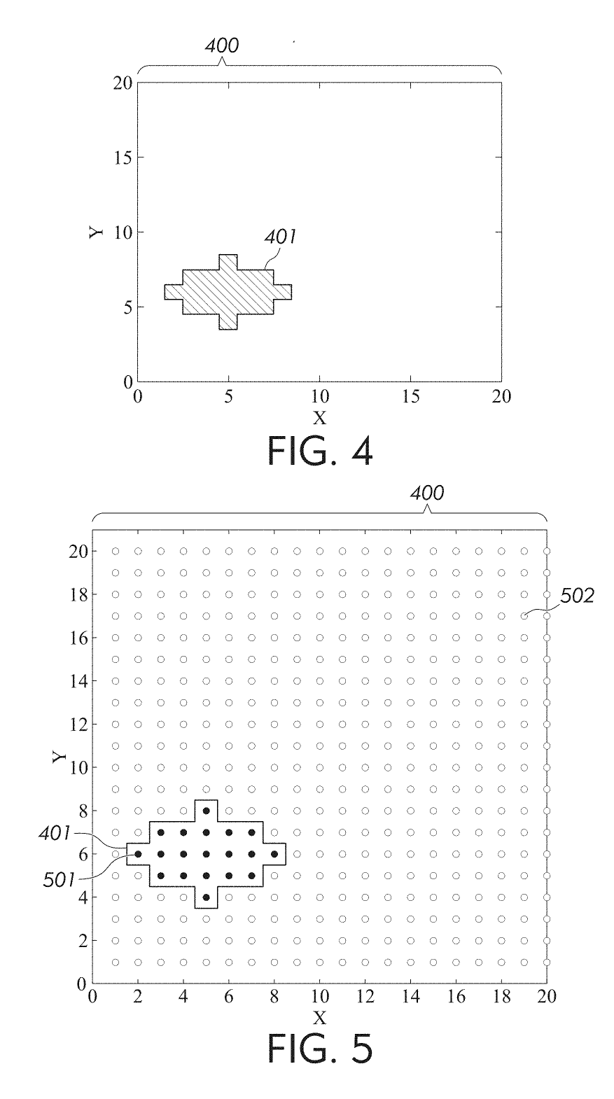

In order to illustrate the approach of the present invention, a sample problem in which a blindfolded player must identify a highlighted region of a dart board is posed. The player must predict where the target is on the opposing wall. The player's goal is to predict the location of the target as quickly and as accurately as possible as shown in FIG. 4.

FIG. 4 illustrates a region 401 (target) that is randomly placed in a dart board 400 comprising a 20 by 20 grid of x-y values in accordance with an embodiment of the present invention. As discussed above, the goal of the player is to predict where region 401 (or analogously, the experimental process window) lies within the 20 by 20 grid of x-y values.

Three possible approaches for helping the player find target 401 on the opposing wall are illustrated herein.

A first approach is the “brute force” method, where every possible experiment is performed. With this method, the blindfolded player is able to precisely and accurately identify the process window of the target albeit with 400 experiments as shown in FIG. 5 in accordance with an embodiment of the present invention. FIG. 5 illustrates that in the brute force approach, the blind folder player throws a dart at all possible locations, where locations 501 indicating a direct hit on target 401 and locations 502 indicating a miss of hitting target 401. The player is able to predict the process window of the dart with 100% accuracy at the penalty cost of 400 experiments.

A second approach is the “Bayesian inference” approach. In the Bayesian inference approach, the blindfolded player uses Bayes' rule to sequentially update the player's prediction of where target 401 should be given prior probability and conditional probability rules. For example, the player can say that the probability of a point on the discretized grid being a “hit” (color “red”) or “miss” (color “white”) is conditionally based on its distance from previously thrown red and white darts. This can be written as:

### Conditional Probabilities

P(red dart/past red event)=1/(distance from past red event+1);

P(white dart/past white event)=1/(distance from past white event+1)

P(red dart/white event)=1−P(white dart/past white event)

P(white dart/past red event)=1−P(red dart/past red event)

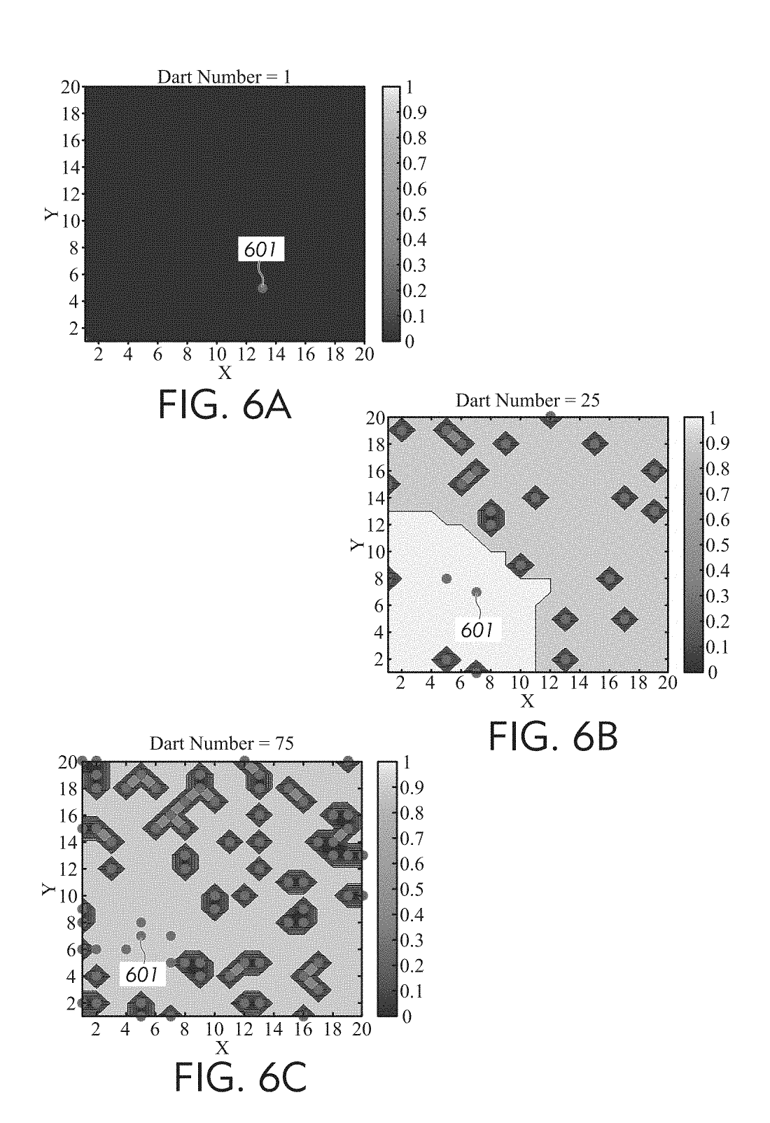

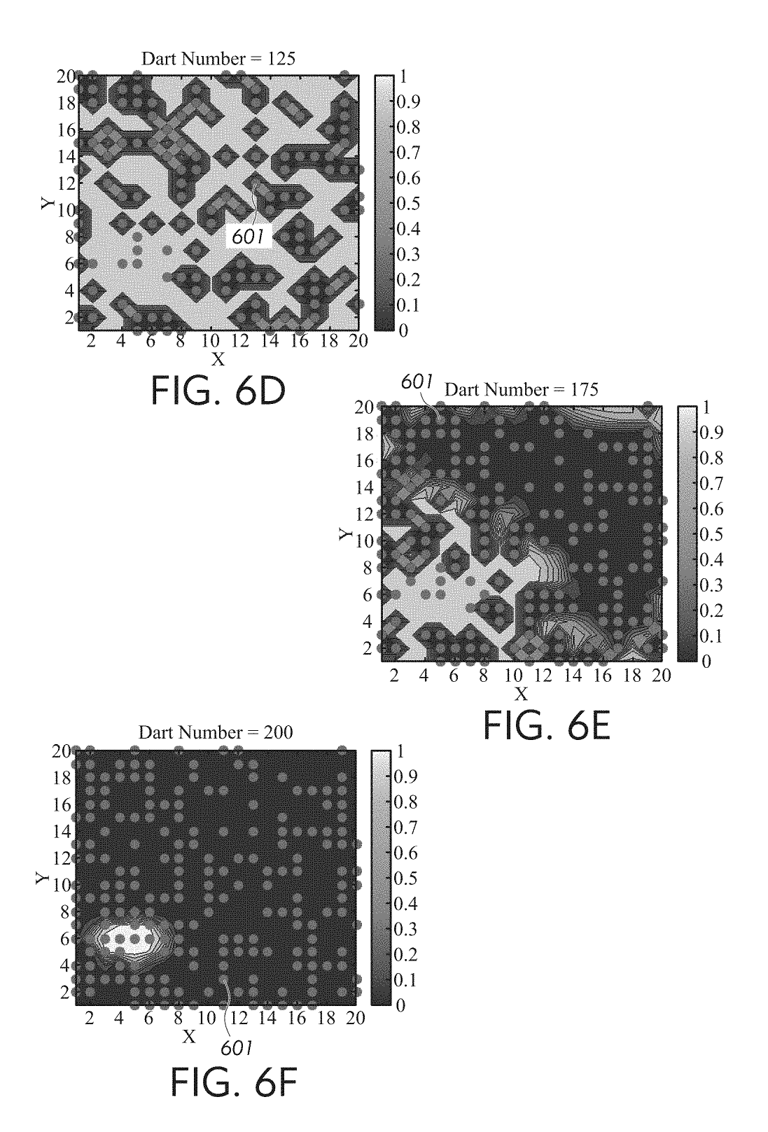

After each dart is thrown, the prior probabilities are updated, and the location of the next dart is picked based on the probability of a red dart being thrown. Here, the simulation is stopped after 50 attempts to choose a new location for the dart are exhausted (no dart throws are allowed to be repeated). Using this method, one can identify target region 401 with only 200 dart throws-half the throws of the brute force method as shown in FIG. 6.

FIGS. 6A-6F illustrate the predicted target area using Bayesian inference in accordance with an embodiment of the present invention. As illustrated in FIGS. 6A-6F, dots 601 represent the darts thrown, where in FIG. 6A, a single dart was thrown. In FIG. 6B, 25 darts were thrown. In FIG. 6C, 75 darts were thrown. In FIG. 6D, 125 darts were thrown. In FIG. 6E, 175 darts were thrown, and in FIG. 6F, 200 darts were thrown. The shaded areas indicate the model's prediction of the target's probable location where the lightest shade is the most probable and the darkest shade is the least probable.

The third approach is the approach of the present invention.

The blindfolded player can use the methodology of the present invention to determine region 401 on the opposing wall. The player assumes an ellipse model for the target where the radii and center of the ellipse are unknown such that (x−h)²/a²+(y−k)²/b²=1 and there are four unknowns in total. For the player's priors, the player assumes that the each of the unknowns is normally distributed N(10,10). Similarly, the player chooses a normal proposal distribution N(10,10). The player uses the present invention to sequentially determine the best experiment to perform to determine the next best experiment to perform. Because the design space is so large (400 experiments are possible), the player limits the possible experiments to perform to a coarse grid over the target process space as illustrated in FIG. 7 in accordance with an embodiment of the present invention.

FIG. 7 is a coarse grid for the target space in accordance with an embodiment of the present invention. Circles 701 represent the possible experimental designs in the coarse grid.

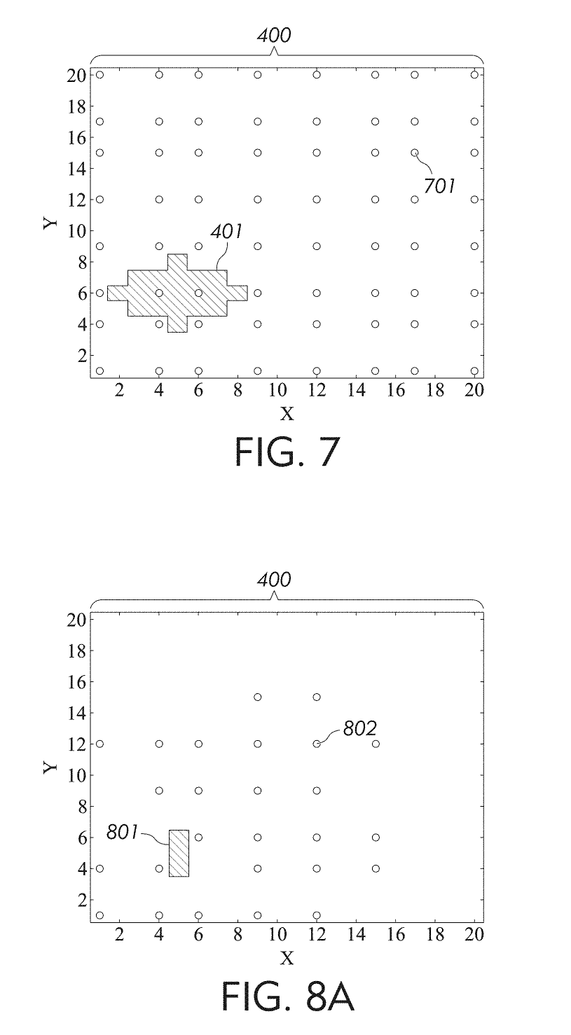

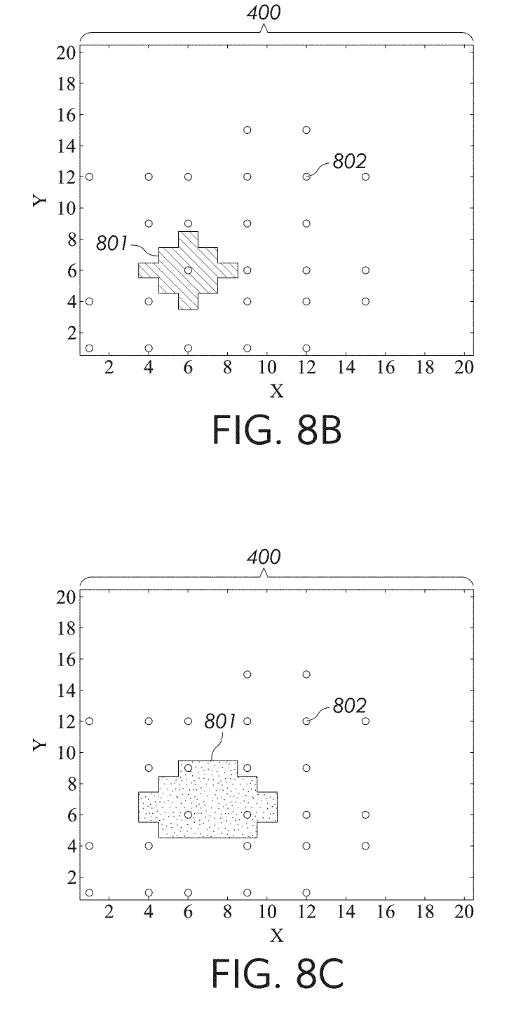

Using the present invention, the player is able to identify the target window 401 within reasonable accuracy. The ellipse predicted using parameter estimates within a 95% confidence interval of the inferred parameter values is shown in FIGS. 8A-8C. FIGS. 8A-8C illustrate the target predictions 801 based off of 25 sequential experiments using μ−σ, μ, and μ+σ, respectively, where represents the mean and a represents the standard deviation, in accordance with an embodiment of the present invention. Circles 802 represent the experiments performed.

The present invention allows the blindfolded player to determine the process window of the ellipse with 1/16 the number of experiments used in the brute force method, and ⅛ the number of the experiments in the purely Bayesian inference method.

To further illustrate the utility of the present invention, the following discusses applying the model of the present invention to plasma etching. In particular, the following discusses applying the model of the present invention to the dry etching of MgO using continuum models.

Etch rate prediction for different reactants and substrate materials can be divided into two different problems. First, a model for the gas chemistry inside the plasma reactor is needed. Second, a model for the surface kinetics of the etched material is necessary to determine etch rate as a function of the fluxes and ion energy in the reactor.

To model the gas chemistry, a global volume average model of high density plasma discharges was developed using known reaction sets from literature. In this model, a uniform distribution of plasma parameter values over the volume of the bulk plasma is assumed and that the negative ion density drops to zero at the edge of the plasma sheath. The electrons are assumed to have a Maxwellian distribution. Moreover, it is also assumed that the temperatures of the positive and negative ions are equal to the neutral gas temperature and inversely proportional to the gas pressure. For a monatomic gas, electron temperature is solved for using the continuity equation such that

k_{iz}nₙnᵢπR²L=nᵢU_{B}(2πR²h_{L}+2πRLh_{R}), (5)

where k_{iz} is the ionization rate coefficient, nᵢ is the ion density, and R and L represent the dimensions of the reactor. The Bohm velocity, U_{B} is approximated by

U_{B}˜(eTₑ/mᵢ)^{1/2} (6)

and the neutral density, nₙ, by the ideal gas law.

P_{reactor}=nₙkT (7)

The continuity equation hₗ and h_{R} represent the ratios of the sheath edge to the bulk ion density as

hₗ=0.86(3+L/(2λ))^{-1/2} and h_{R}=0.8(4+R/λ)^{(-1/2)} (8)

where λ=1/(n_{g}σᵢ).

A power balance equation can then be used to determine the ion density in the plasma sheath,

P=Aeε_{T}U_{B}nᵢₛ, (9)

where A is the area of the reactor, e is electron charge, nᵢₛ is the ion density in the sheath, and ε_{T} represents energy loss per electron ion-pair created and can be approximated as ˜8Tₑ.

For molecular gases, the volume densities of the neutral and charged particles can be estimated from the kinetic and mass balance equations of the reactant gases as well as the quasineutrality condition,

nₑₛ=Σᵢ₌₁^{γ}=nᵢₛ (10)

For molecular gases and gas mixtures, the power balance equation is modified to incorporate generation of positive and negative ions, fragmentation of the neutral molecule, and additional energy-loss channels. The system of equations is solved using specified inputs for discharge length and diameter, absorbed power, pressure, feed gas composition, reaction rate coefficients, and surface recombination constants to determine species densities and electron temperatures.

The surface kinetics model is assumed to follow classical Langmuir principles. In the Langmuir model, the surface of the substrate is composed of bare sites where the neutrals absorb and sites occupied by neutrals on which bombarding ions activate chemical reactions. The etch rate is assumed to be a function of chemical etching and physical sputtering,

(1−θ)γSΓ_{C}+(1−θ)YΓₚ, (11)

where γ is the probability of the chemical reaction, Γ_{C} is the flux of the reacting species, S is the sticking probability, Y is the sputtering yield, and Γₚ is the flux of the sputtering species. S and Y are unknown parameters and are specific to the material and reactants being used for the etch process.

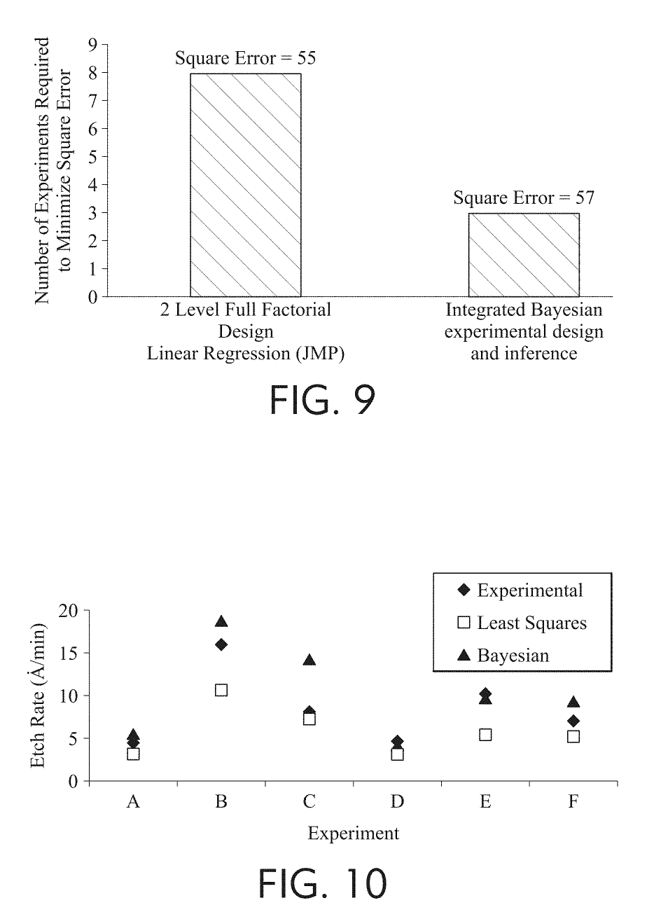

The methodology of the present invention was applied based on the global plasma model to synthetic and experimental results. FIG. 9 shows a comparison between the traditional full factorial design method and the integrated approach over a series of synthetic experiments in accordance with an embodiment of the present invention. Using the physics based model and sequential Bayesian experimental design, the number of experiments required to minimize model error is significantly reduced. In particular, the model was calibrated using a least squares method and Bayesian inference against a random set of three conditioning data points. These results were compared against a test set of experimental results. Total prediction error for both methods was the same.

Next, both methods were evaluated using experimental data. Etch rates of MgO films under a variety of process conditions were determined using ellipsometry. Ten experiments were used to calibrate an ordinary least squares (OLS) model while six experiments were used to calibrate the model of the present invention. Both models' predictions were then evaluated against a test set of experimental data as shown in FIG. 10, where FIG. 10 illustrates the experimental and predicted etch rates for different processing conditions in accordance with an embodiment of the present invention. The model of the present invention had a square error of 3.5 while the OLS model had a square error of 3.4. These results indicate that using the model of the present invention, it is possible to reduce the total number of optimization experiments performed while achieving equal or better prediction accuracy as compared with traditional regression fitting methods.

Hence, the principles of the present invention optimize the nanomanufacturing process by using an integrated Bayesian statistics and continuum model approach to reduce the time to development while enabling applications in areas that are challenging to manufacture, including magnetic memory, nanophotonic devices, metamaterial structures and biomedical applications. Such an approach is much faster and less expensive in identifying optimal process conditions in comparison to existing methods.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for optimizing a manufacturing or fabrication process, the method comprising:
receiving a selection of a model;
receiving a set of parameters for said selected model;
adopting a prior distribution of values for said set of model parameters which summarizes any known information for said set of model parameters;
specifying a utility function which reflects a purpose of an experiment;
selecting an experimental design from a set of experimental designs which maximizes said utility function;
selecting experimental data from a sample space of data based on said selected experimental design;
using a Bayesian technique to calculate a posterior distribution of values for said set of model parameters based on said selected experimental data and said prior distribution of values for said set of model parameters;
selecting said posterior distribution of values for said set of model parameters in response to a model uncertainty reaching a threshold; and
adjusting, by a processor, the manufacturing or fabrication process to manufacture or fabricate a device using said selected posterior distribution of values for said set of model parameters.

2. The method as recited in claim 1 further comprising:
receiving a section of a second experimental design from said set of experimental designs in response to said model uncertainty not reaching said threshold;
selecting a second experimental data from said sample space of data based on said selected second experimental design;
using a Bayesian technique to calculate a posterior distribution of values for said set of model parameters based on said selected second experimental data and said prior distribution of values for said set of model parameters; and
determining if said model uncertainty reaches said threshold.

3. The method as recited in claim 1, wherein said prior distribution of values for said set of model parameters is independent of information provided by said selected experimental data.

4. The method as recited in claim 1, wherein said Bayesian technique comprises Gibbs Sampling.

5. The method as recited in claim 1 further comprising:
calibrating said model by fitting said distribution of values for said set of model parameters.

6. The method as recited in claim 1, wherein said model is a continuum model.

7. The method as recited in claim 1, wherein said model is a plasma etch or deposition model.

8. A computer program product for optimizing a manufacturing or fabrication process, the computer program product comprising a computer readable storage medium having program code embodied therewith, the program code comprising the programming instructions for:
receiving a selection of a model;
receiving a set of parameters for said selected model;
adopting a prior distribution of values for said set of model parameters which summarizes any known information for said set of model parameters;
specifying a utility function which reflects a purpose of an experiment;
selecting an experimental design from a set of experimental designs which maximizes said utility function;
selecting experimental data from a sample space of data based on said selected experimental design;
using a Bayesian technique to calculate a posterior distribution of values for said set of model parameters based on said selected experimental data and said prior distribution of values for said set of model parameters;
selecting said posterior distribution of values for said set of model parameters in response to a model uncertainty reaching a threshold; and
adjusting the manufacturing or fabrication process to manufacture or fabricate a device using said selected posterior distribution of values for said set of model parameters.

9. The computer program product as recited in claim 8, wherein the program code further comprises the programming instructions for:
receiving a section of a second experimental design from said set of experimental designs in response to said model uncertainty not reaching said threshold;
selecting a second experimental data from said sample space of data based on said selected second experimental design;
using a Bayesian technique to calculate a posterior distribution of values for said set of model parameters based on said selected second experimental data and said prior distribution of values for said set of model parameters; and
determining if said model uncertainty reaches said threshold.

10. The computer program product as recited in claim 8, wherein said prior distribution of values for said set of model parameters is independent of information provided by said selected experimental data.

11. The computer program product as recited in claim 8, wherein said Bayesian technique comprises Gibbs Sampling.

12. The computer program product as recited in claim 8, wherein the program code further comprises the programming instructions for:
calibrating said model by fitting said distribution of values for said set of model parameters.

13. The computer program product as recited in claim 8, wherein said model is a continuum model.

14. The computer program product as recited in claim 8, wherein said model is a plasma etch or deposition model.

15. A system, comprising:
a memory unit for storing a computer program for optimizing a manufacturing or fabrication process; and
a processor coupled to the memory unit, wherein the processor is configured to execute the program instructions of the computer program comprising:
receiving a selection of a model;
receiving a set of parameters for said selected model;
adopting a prior distribution of values for said set of model parameters which summarizes any known information for said set of model parameters;
specifying a utility function which reflects a purpose of an experiment;
selecting an experimental design from a set of experimental designs which maximizes said utility function;
selecting experimental data from a sample space of data based on said selected experimental design;
using a Bayesian technique to calculate a posterior distribution of values for said set of model parameters based on said selected experimental data and said prior distribution of values for said set of model parameters;
selecting said posterior distribution of values for said set of model parameters in response to a model uncertainty reaching a threshold; and
adjusting the manufacturing or fabrication process to manufacture or fabricate a device using said selected posterior distribution of values for said set of model parameters.

16. The system as recited in claim 15, wherein the program instructions of the computer program further comprise:
receiving a section of a second experimental design from said set of experimental designs in response to said model uncertainty not reaching said threshold;
selecting a second experimental data from said sample space of data based on said selected second experimental design;
using a Bayesian technique to calculate a posterior distribution of values for said set of model parameters based on said selected second experimental data and said prior distribution of values for said set of model parameters; and
determining if said model uncertainty reaches said threshold.

17. The system as recited in claim 15, wherein said prior distribution of values for said set of model parameters is independent of information provided by said selected experimental data.

18. The system as recited in claim 15, wherein said Bayesian technique comprises Gibbs Sampling.

19. The system as recited in claim 15, wherein the program instructions of the computer program further comprise:
calibrating said model by fitting said distribution of values for said set of model parameters.

20. The system as recited in claim 15, wherein said model is a continuum model.

21. The system as recited in claim 15, wherein said model is a plasma etch or deposition model.
